(19) United States
(12) Patent Application Publication
(10) Pub. No.: US 2019/0148496 A1
(43) Pub. Date: May 16, 2019

(54) SIC EPITAXIAL WAFER

(71) Applicant: SHOWA DENKO K.K., Tokyo (JP)

(72) Inventors: Naoto ISHIBASHI, Chichibu-shi (JP); Keisuke FUKADA, Chichibu-shi (JP)

(73) Assignee: SHOWA DENKO K.K., Tokyo (JP)

(21) Appl. No.: 16/152,971

(22) Filed: Oct. 5, 2018

(30) Foreign Application Priority Data
Nov. 14, 2017 (JP) 2017-219397

(51) Int. Cl. H01L 29/16; H01L 29/06; H01L 21/02; H01L 29/04

(52) U.S. Cl. CPC H01L 29/1608; H01L 29/06; H01L 21/02529; H01L 21/0262; H01L 29/045; H01L 21/02579; H01L 21/02433; H01L 21/02634; H01L 21/02576

(57) ABSTRACT

An SiC epitaxial wafer according to the present invention includes: an SiC single crystal substrate; and a carrier concentration variation layer disposed on one face side of the SiC single crystal substrate, wherein the carrier concentration variation layer includes: high concentration layers in which carrier concentrations thereof are higher than carrier concentrations of adjacent layers; and low concentration layers in which carrier concentrations are lower than in adjacent layers, and the high concentration layers and the low concentration layers are laminated alternately.

### TECHNICAL FIELD

The present invention relates to a SiC epitaxial wafer.

### BACKGROUND OF THE INVENTION

Silicon carbide (SiC) has: a breakdown electric field larger than that of silicon (Si) by one order of magnitude; a band gap three times as larger as that of Si; and a thermal conductivity approximately three times as high as that of Si. Accordingly, silicon carbide (SiC) has been expected to be applied to power device, high-frequency device, high-temperature operational device, or the like.

It is required to establish a high-quality SiC epitaxial wafer and a high-quality epitaxial growth-technique so as to promote the practical realization of the Sic device.

A SiC device is formed on a SiC epitaxial wafer including: a SiC substrate; and an epitaxial layer laminated on the substrate. The SiC substrate is obtained by processing SiC bulk single crystals grown by a sublimation-recrystallization method or the like. The epitaxial layer is formed by a chemical vapor deposition (CVD) method or the like and becomes an active area of the device.

The epitaxial layer is further specifically formed on a SiC substrate having, as a growth surface, a face with an off-angle in the <11-20> direction from the (0001) face. The epitaxial layer is step-flow grown (grown from atomic step in a transverse direction) on the SiC substrate to form 4H-SiC.

In the SiC epitaxial wafer, basal plane dislocations (BPDs) are known as device killer-defects which cause critical defects on the SiC device.

Most of the basal plane dislocations in the SiC substrate are converted to threading edge dislocations (TEDs) when the epitaxial layer is formed. In contrast, a part of the basal plane dislocations carried over in the epitaxial layer become device killer defects. When forward current is applied to the device, and a small amount of carriers reaches the basal plane dislocations, the basal plane dislocations are extended to become highly-resistive stacking faults. When highly-resistive portions generate in the device, the reliability of the device decreases.

Patent Document 1 discloses a method for increasing the conversion efficiency of from the basal plane dislocations to the threading edge dislocations. A SiC epitaxial wafer disclosed in Patent Document 1 includes a dislocation conversion layer in which the carrier concentration is increased stepwise. The dislocation conversion layer contributes increase in the conversion efficiency of from the basal plane dislocations to the threading edge dislocations and suppresses the presence of the basal plane dislocations in a drift layer on which a device is formed.

### DOCUMENTS OF RELATED ART

### Patent Documents

Patent Document 1: Japanese Patent No. 548509

### SUMMARY OF THE INVENTION

### Problems to be Solved by the Invention

In recent years, it has been attempted to increase the size of a SiC epitaxial wafer to a diameter of 150 mm or more so as to increase the number of SiC devices taken from an epitaxial wafer to reduce the manufacturing cost. Accordingly, it has been demanded that the basal plane dislocation density is low in a large-sized SiC epitaxial wafer having a diameter of 150 mm or more.

However, the SiC epitaxial wafer disclosed in Patent Document 1 has a diameter of 50 mm. Even if the method disclosed in Patent Document 1 is applied to a large-sized SiC epitaxial wafer, the basal plane dislocations cannot be sufficiently removed from an epitaxial layer.

The present invention aims to obtain a SiC epitaxial wafer in which the amount of basal plane dislocations, which become device killer defects, is low, in view of the above-mentioned problems.

### Means to Solve the Problems

The present invention provides the following aspects to solve the problems.

(1) A SiC epitaxial wafer according to the first aspect includes: a SiC single crystal substrate; and a carrier concentration variation layer disposed on one face side of the SiC single crystal substrate, wherein the carrier concentration variation layer includes: high concentration layers in which carrier concentrations thereof are higher than carrier concentrations of adjacent layers; and low concentration layers in which carrier concentrations are lower than in adjacent layers, and the high concentration layers and the low concentration layers are laminated alternately.
(2) In the SiC epitaxial wafer, the thickness of the respective high concentration layers and the respective low concentration layers may be 0.5 μm or less.
(3) In the SiC epitaxial wafer, at least one high concentration layer of the high concentration layers may have a carrier concentration at least two times higher than carrier concentrations of low concentration layers adjacent thereto.
(4) In the SiC epitaxial wafer, an average value of the carrier concentrations of the high concentration layers may be at least two times higher than an average value of the carrier concentrations of the low concentration layers.
(5) In the SiC epitaxial wafer, an average carrier concentrations of the carrier concentration variation layer may be 1×10¹⁸ atoms/cm³ or more.
(6) In the SiC epitaxial wafer, the SiC single crystal substrate, a buffer layer laminated on one face of the SiC single crystal substrate, and a drift layer laminated on the buffer layer are equipped, wherein a portion or an entire portion of the buffer layer may serve as the carrier concentration variation layer.

### Effects of the Invention

A SiC epitaxial wafer according to the present invention makes it possible to suppress basal plane dislocations which become device-killer defects.

### BRIEF DESCRIPTION OF DRAWINGS

FIG. 1 is a cross-sectional schematic view showing a SiC epitaxial wafer of an aspect according to the present invention.

FIG. 2 is a cross-sectional schematic view showing a SiC epitaxial wafer of another aspect according to the present invention.

FIG. 3A shows results obtained by measuring the carrier concentration distribution in a thickness-direction of an epitaxial layer in Example 1.

FIG. 3B shows results obtained by measuring the carrier concentration distribution in a thickness-direction of an epitaxial layer in Comparative Example 1.

FIG. 4A shows results obtained by measuring the basal plane dislocation distribution in an epitaxial layer in Example 1.

FIG. 4B shows results obtained by measuring the basal plane dislocation distribution in an epitaxial layer in Comparative Example 1.

FIG. 5A is a cross-sectional schematic view showing a first embodiment in which a carrier concentration variation layer 2 constitutes a portion of a buffer layer.

FIG. 5B is a cross-sectional schematic view showing a second embodiment in which a carrier concentration variation layer 2 constitutes a portion of a buffer layer.

### EMBODIMENTS FOR CARRYING OUT THE INVENTION

Hereinafter, an aspect according to the present invention, which is a preferable embodiment of the present invention, will be explained with reference to drawings appropriately. In the drawings referred in the following description, there are cases in which the characteristic parts are shown enlarged for convenience in order to make their characteristics easily understood, and the relative dimensions of each of the elements are not always the same as in real ones. Furthermore, the following description illustrates one example of the materials, dimensions, constitutions, and the like. This is not a limitation of the present invention, and appropriate changes may be made provided they do not change the gist of the invention.

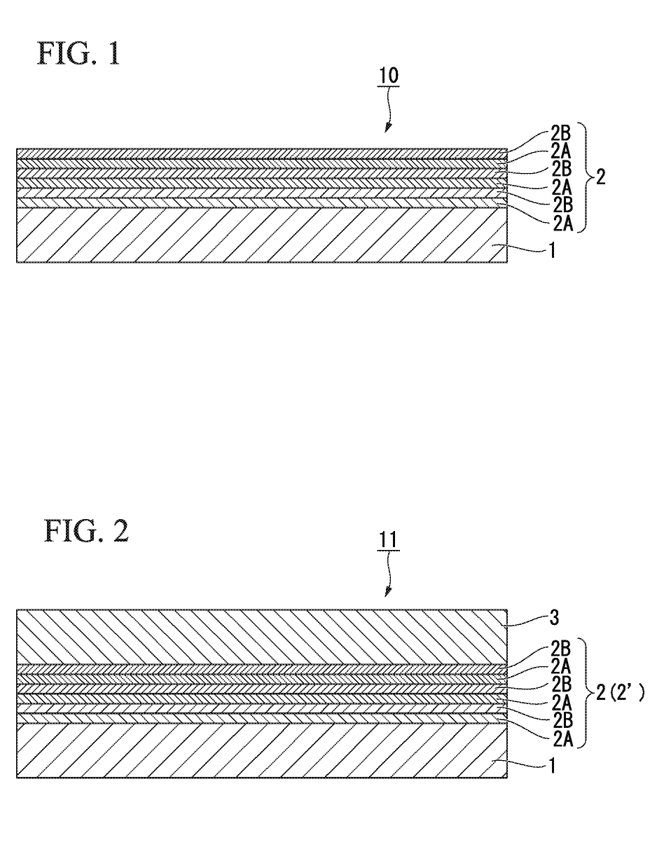

FIG. 1 is a cross-sectional schematic view of a SiC epitaxial wafer 10 of an aspect according to the present invention. The SiC epitaxial wafer 10 shown in FIG. 1 includes: a SiC single crystal substrate 1 and a carrier concentration variation layer 2.

A SiC ingot obtained by sublimation may be sliced to utilize the resultant as the SiC single crystal substrate 1. In the present specification, the term “SiC epitaxial wafer” means a wafer in which an epitaxial layer is formed, and the term “SiC single crystal substrate” means a wafer in which an epitaxial layer is not formed.

In the SiC single crystal substrate 1, basal plane dislocations are present along the (0001) face (c face). Although it is preferable that the number of basal plane dislocations appearing on a growth surface of the SiC substrate be small, the number is not particularly limited. In the state of the art at the present stage, the number of basal plane dislocations present in a face (growth surface) of a SiC substrate having a diameter of 150 mm is approximately 1000 to 5000 per cm².

There are many cases in which the SiC single crystal substrate 1 has a face with an offset-angle in the <11-20> direction from the (0001) face as a growth surface. That is, the basal plane dislocations are present while being tilted against the growth surface.

Although the thickness of the SiC single crystal substrate 1 is not particularly limited, the thickness is preferably approximately 300 to 400 μm.

The carrier concentration variation layer 2 is laminated on one face side of the SiC single crystal substrate 1. The carrier concentration variation layer 2 may be laminated directly on the SiC single crystal substrate 1, or may be laminated thereon while interposing at least one additional layer therebetween.

In the carrier concentration variation layer 2, a plurality of high concentration layers 2A and a plurality of low concentration layers 2B are laminated alternately. The carrier concentration in the respective high concentration layers 2A is higher than that of the low concentration layers 2R adjacent thereto, and the carrier concentration in the respective low concentration layers 2B is lower than that of the high concentration layers 2A adjacent thereto.

Nitrogen, boron, titanium, vanadium, aluminum, gallium, phosphorus, or the like may be used as impurities to be doped in the carrier concentration variation layer 2.

The thickness of the respective high concentration layers 2A and the respective low concentration layers 2B is preferably 0.5 μm or less, more preferably 0.1 μm or less, and even more preferably 0.05 μm or less. It is possible to reduce the basal plane dislocation density in the SiC epitaxial wafer by laminating the high concentration layers 2A and the low concentration layers 2B alternately and repeatedly at short cycles (the respective thickness of the high concentration layers 2A and the low concentration layers 2B is extremely thin).

In contrast, the respective thickness of the high concentration layers 2A and the low concentration layers 2B is preferably 0.002 μm or more.

It is preferable that the carrier concentration of at least one high concentration layer 2A of the high concentration layers 2A be at least two times, and more preferably three times, higher than the carrier concentrations of the low concentration layers 2B adjacent thereto. The lattice constant of a crystal constituting an epitaxial layer becomes large when the carrier concentration is high. Accordingly, in the case where the difference between the carrier concentrations of the high concentration layer 2A and the low concentration layer 2B adjacent thereto is large, the lattice constant variation becomes large. In the case where the lattice constant variation between the adjacent layers is large, it is assumed that the conversion of from basal plane dislocations to threading edge dislocation between the layers occurs easily.

It is preferable that the average value of carrier concentrations of the high concentration layers 2A be at least two times, and more preferably three times, higher than the average value of the carrier concentrations of the low concentration layers 2B. The phrase “average value of carrier concentrations of high concentration layers (or low concentration layers)” means an average value of all of the plurality of the high concentration layers 2A (or low concentration layers 2B). It is preferable that the difference between the carrier concentrations of the high concentration layers 2A and the low concentration layers 2B be sufficiently present not only between adjacent layers from a micro-viewpoints but also from a macro-viewpoints.

In contrast, although the average value of the carrier concentrations of the high concentration layers 2A is not particularly limited, it is preferable that the average value of the carrier concentrations of the high concentration layers 2A be five times or less higher than the average value of the carrier concentrations of the low concentration layers 2B.

It is preferable that the average value of the carrier concentrations of the high concentration layers 2A be 3×10¹⁸ atoms/cm³ or more, more preferably 7×10¹⁸ atoms/cm³ or more, and even more preferably 1×10¹⁹ atoms/cm³ or more.

In contrast, it is preferably that the average value of the carrier concentrations of the high concentration layers 2A be 2×10¹⁹ atoms/cm³ or less.

It is preferable that the average value of the carrier concentrations of the low concentration layers 2B be 5×10¹⁸ atoms/cm³ or less, more preferably 3×10¹⁸ atoms/cm³ or less, and even more preferably 7×10¹⁷ atoms/cm³ or less.

In contrast, it is preferable that the average value of the carrier concentrations of the low concentration layers 2B be 5×10¹⁷ atoms/cm³ or more.

It is preferable that the average carrier concentration of the carrier concentration variation layer 2 be 1×10¹⁸ atoms/cm³ or more, more preferably 5×10¹⁸ atoms/cm³ or more, and even more preferably 7×10¹⁸ atoms/cm³ or more. It is preferable that the average value of the high concentration layers 2A, relative to the average carrier concentration of the carrier concentration variation layer 2, be at least 1.4 times or more, and more preferably 1.73 times or more. It is preferable that the average value of the low concentration layers 2B, relative to the average carrier concentration of the carrier concentration variation layer 2, be 0.7 times or less, and more preferably 0.58 times or less.

In contrast, it is preferable that the average carrier concentration of the carrier concentration variation layer 2 be 1.2×10¹⁹ atoms/cm³ or less.

The phrase “average carrier concentration of the carrier concentration variation layer 2” means the average carrier concentration of an entire carrier concentration variation layer 2, which is obtained by dividing the sum of the carrier concentrations of each layers by the number of layers. In the case where the average carrier concentration of the carrier concentration variation layer 2 is highs, the lattice constant variation between the high concentration layers 2A and the low concentration layers 2B becomes large. In the case where the average carrier concentration of the carrier concentration variation layer 2 is high, it is possible to suppress an expansion of defects caused by generating Shockley-type stacking faults when an electrical current is applied in a forward direction of a bipolar device having basal plane dislocations. That is, it is possible to suppress the deterioration of forward direction characteristics of the device.

FIG. 2 is a cross-sectional schematic view of a SiC epitaxial wafer of another aspect according to the present invention. The SiC epitaxial wafer 11 shown in FIG. 2 includes: the SiC single crystal substrate 1; the carrier concentration variation layer 2 (buffer layer 2′); and a drift layer 3.

The drift layer 3 is a layer in which a SiC device is formed. The carrier concentration of the drift layer 3 is lower than the carrier concentration of the SiC single crystal substrate 1. The carrier concentration of the carrier concentration variation layer 2 is higher than the carrier concentration of the drift layer 3. The relation between the carrier concentrations of the carrier concentration variation layer 2 and the SiC single crystal substrate 1 is not particularly limited, the carrier concentration of the carrier concentration variation layer 2 may be lower than, approximately equal to, or high than the carrier concentration of the SiC single crystal substrate 1. In the aspect shown in FIG. 2, the carrier concentration variation layer 2 locates between the SiC single crystal substrate 1 and the drift layer 3 and serves as the buffer layer 2′.

The thickness of the drift layer 3 is approximately 5 to 50 μm.

The most of the basal plane dislocations in the carrier concentration variation layer 2 (buffer layer 2′) is converted to the threading edge dislocations. Accordingly, the most of the basal plane dislocations does not reach to the drift layer 3. In the case where the basal plane dislocations are contained in the drift layer 3, the forward direction characteristics of the SiC device are deteriorated. It is possible to suppress the deterioration of the device caused by the basal plane dislocations by laminating the drift layer 3 on the carrier concentration variation layer 2 (buffer layer 2′).

In FIG. 2, the carrier concentration variation layer 2 and the buffer layer 2′ are in one-to-one correspondence. That is, the carrier concentration variation layer 2 constitutes an entire portion of the buffer layer 2′. On the other hand, the carrier concentration variation layer 2 may constitute one portion of a buffer layer.

In the case where the carrier concentration variation layer 2 constitutes on portion of the buffer layer, the buffer layer may include a carrier concentration constant layer, for example, in addition to the carrier concentration variation layer 2. For example, the following constitution may be adapted.

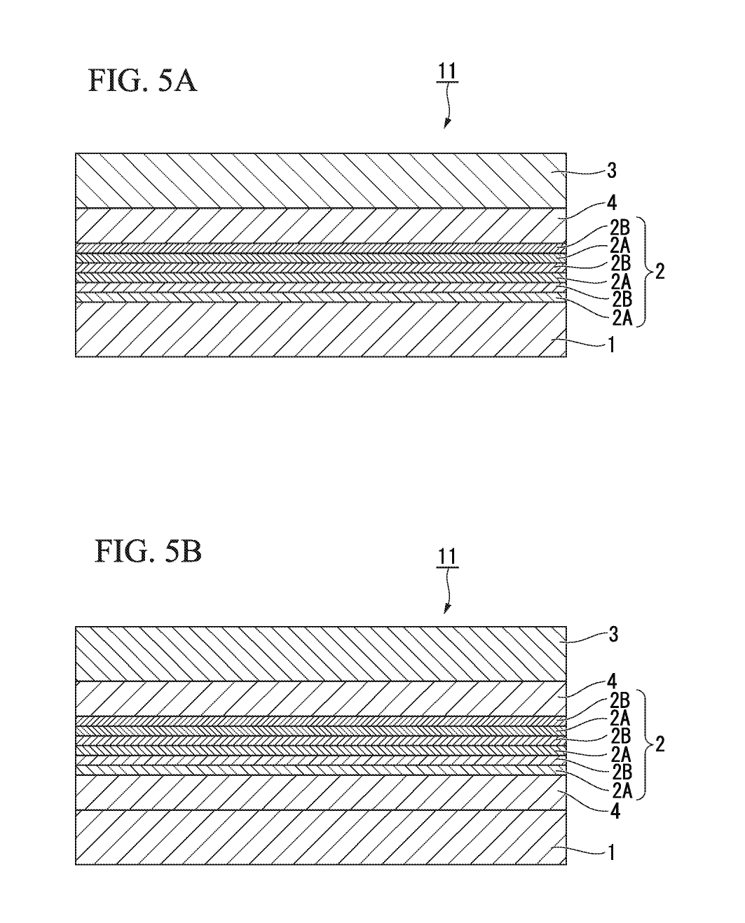

In the first embodiment in which the carrier concentration variation layer 2 constitutes one portion of a buffer layer, as shown in FIG. 5A, the carrier concentration variation layer 2 is laminated between the SiC single crystal substrate 1 and the carrier concentration constant layer 4.

In the second embodiment in which the carrier concentration variation layer 2 constitutes one portion of a buffer layer, as shown in FIG. 5B, the carrier concentration constant layer 4 is laminated between the SiC single crystal substrate 1 and the carrier concentration variation layer 2, and the carrier concentration constant layer 4 is laminated between the carrier concentration variation layer 2 and the drift layer 3.

It is preferable that the average carrier concentration in the carrier concentration constant layer 4 be 1×10¹⁸ atoms/cm³ to 1.2×10¹⁹ atoms/cm³.

It is preferable the thickness of the carrier concentration constant layer 4 be approximately 1 to 10 μm.

In the first aspect in which the carrier concentration variation layer 2 is laminated on one face side of the SiC single crystal substrate 1, as shown in FIG. 1, the SiC epitaxial wafer 10 is obtained by conducting: a first step in which the SiC single crystal substrate 1 is prepared; and a second step in which the carrier concentration variation layer 2 is laminated thereon.

In the first step, the SiC single crystal substrate 1 is prepared. There is no particular limitation on a preparation method of the SiC single crystal substrate 1. For example, the SiC single crystal substrate 1 may be obtained by slicing a SiC ingot obtained by a sublimation method or the like.

Then, the carrier concentration variation layer 2 is laminated thereon in the second step. The carrier concentration variation layer 2 is laminated on one face of the SiC single crystal substrate 1 by conducting a chemical vapor deposition (CVD) method, or the like, for example. In the case where a lamination face of the SiC single crystal substrate 1 has an offset angle in the <11-20> direction from the (0001) face, the carrier concentration variation layer 2 is step-flow grown (grown from atomic step in a transverse direction).

The epitaxial growth is conducted by making raw material gas and dopant gas flow on a SiC single crystal substrate, the temperature of which is maintained at a high temperature (preferably, approximately at 1550° C. to 1650° C.).

The raw material gas is a gas that becomes a raw material when a SiC epitaxial layer is formed. The raw material gas is generally classified into: a Si-based raw material gas in which Si is contained in a molecule thereof; and a C-based raw material gas in which C is contained in a molecule thereof.

As the Si-based raw material gas, conventionally known ones are available, and silane (SiH₄) may be used. In addition, chloride-based Si raw material gas, which contains Cl, (chloride-based raw material) having an etching action, such as dichlorosilane (SiH₂Cl₂), trichlorosilane (SiHCl₃), or tetrachlorosilane (SiCl₄), may be used. As the C-based raw material gas, propane (C₃H₈) may be used, for example.

The dopant gas is a gas containing an element that becomes a donor or an acceptor (carrier). Examples of the dopant gas include: nitrogen which contributes in N-type growth; and trimethylaluminum (TMA) and triethylaluminum (TEA), which contribute in P-type growth.

In addition, a gas or the like, which contributes in carrying the above-mentioned gas into reactor, may be used together. For example, hydrogen or the like, which is inert against SiC, may be used, for example.

As a preferable method to laminate the carrier concentration variation layer 2, there is a method in which a supply amount of a dopant gas among these gas is changed over time. In the case where the supply amount of the dopant gas increases, a lot of the dopant gas is incorporated into the epitaxial layer to become high concentration layers. In the case where the supply amount of the dopant gas decreases, the amount of the dopant gas incorporated into the epitaxial layer decreases to become low concentration layers.

Although the supply amount of the dopant gas to form the high concentration layers 2A is appropriately selected, the supply amount of the dopant gas to form the high concentration layers 2A is, for example, at least two times, or more preferably at least three times, higher than the supply amount of the dopant gas to form the low concentration layers 2B, and ten times or less, or more preferably five times or less, higher than the supply amount of the dopant gas to form the low concentration layers 2B.

On the other hand, the film forming rates of the high concentration layers 2A and that of the low concentration layers 2B are the same as each other and are approximately 40 to 100 μm/h.

A method to laminate the carrier concentration variation layer 2 is not limited to the above-mentioned method, and different methods may be adopted. For example, the constitution of the raw material gas may be changed over time. In the case where the ratio of SiC in the raw material gas is changed, the dopant incorporation efficiency changes, and then layers having different carrier concentrations (high concentration layers 2A and low concentration layers 2B) are laminated.

For example, the SiC ratio of the raw material gas to form the high concentration layers 2A is preferably approximately 0.8 to 1.0, and the SiC ratio of the raw material gas to form the low concentration layers 2B is preferably approximately 1.0 to 1.15.

In the case where a SiC single crystal substrate is rotated, the carrier concentration variation layer 2 may be formed by making the concentration distribution of the dopant gas or the constitution distribution of the raw material gas generate, or changing the temperature distribution, in a circumferential direction of the rotation.

In the second aspect in which the buffer layer 2′ is laminated on one face of the SiC single crystal substrate 1, as shown in FIG. 2, the SiC epitaxial wafer 11 is obtained by preparing the SiC single crystal substrate 1 in the first step and laminating the buffer layer 2′ thereon in the second step.

In the first step, the SiC single crystal substrate 1 is prepared in the same way as that of the first aspect.

Then, the buffer layer 2′ is laminated thereon in the second step. The lamination of the buffer layer 2′ is conducted by a conventionally known method. For example, a chemical vapor deposition (CVD) method or the like may be used.

Specifically, a drift layer 3 may be laminated on a laminated body (in which a buffer layer 2′ is laminated on one face of the SiC single crystal substrate 1), the temperature of which is maintained at approximately 1550 to 1650° C., by making a raw material gas flow thereon. As the raw material gas, silane (SiH₄) or propane (C₃H₈) may be used, for example.

An additional gas or the like, which contributes in carrying the raw material gas into a reactor, may be used together. For example, hydrogen or the like, which is inert against SiC, may be used, for example.

Finally, a drift layer 3 is laminated on the buffer layer 2′ in the third step. The drift layer 3 is laminated by a conventionally known method. For example, a chemical vapor deposition (CVD) method or the like may be used. Specifically, the drift layer 3 may be laminated on a laminated body (in which the buffer layer 2′ is laminated on one face of the SiC single crystal substrate 1), the temperature of which is maintained at approximately 1550° C. to 1650° C., by making the raw material gas flow thereon. As the raw material gas, silane (SiH₄) or propane (C₃H₈) may be used, for example.

An additional gas or the like, which contributes in carrying the raw material gas into a reactor, may be used together. For example, hydrogen or the like, which is inert against SiC, may be used, for example.

As described above, the SiC epitaxial wafer according to the present invention has a carrier concentration variation layer in which the carrier concentrations are changed in short cycles, and therefore it is possible to suppress that basal plane dislocations (BPD) which become device-killer defects of a SiC device are carried over in an epitaxial layer. Accordingly, it is possible to limit the basal plane dislocations which become device-killer defects in the SiC epitaxial wafer according to the present embodiment.

Since a high current as much as 100 A is applied to one device in a module or the like, which is to be applied to automobile or the like, a SiC chip (substrate of a SiC device) produced from a SiC epitaxial wafer is enlarged to a size as large as a 10 mm square. An effect of the basal plane dislocation density on an efficiency of obtaining such enlarged SiC chips is very high, and it is very important to reduce the basal plane dislocation density.

### EXAMPLES

### Example 1

A SiC single crystal substrate having a diameter of 100 mm was prepared. The prepared SiC single crystal substrate is a 4H-type polytype and the main face thereof has a Si face having an offset angle of 4° in the <11-20> direction from the (0001) face.

Then, the SiC single crystal substrate is introduced into a reactor, and a raw material gas (composed of trichlorosilane, propane, and hydrogen chloride) is introduced at a growth temperature of 1600° C. to conduct the epitaxial growth. Nitrogen was used as a doping gas. At the time, the dopant incorporation efficiency was changed by changing the ratio C/Si at the growth in a range from 0.8 to 1.0 over time.

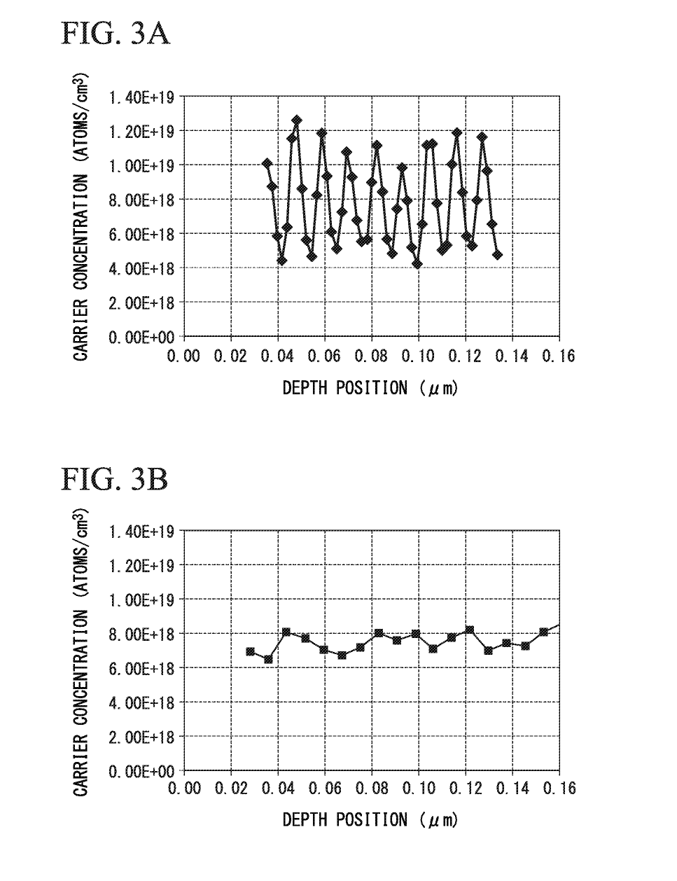

Then, the carrier concentration in a thickness direction of the obtained epitaxial layer was measured using secondary ion mass spectrometer (SIMS). The carrier concentration in a thickness direction was measured using SIMS while shaving the epitaxial layer in a depth direction. The results thereof are shown in FIG. 3A.

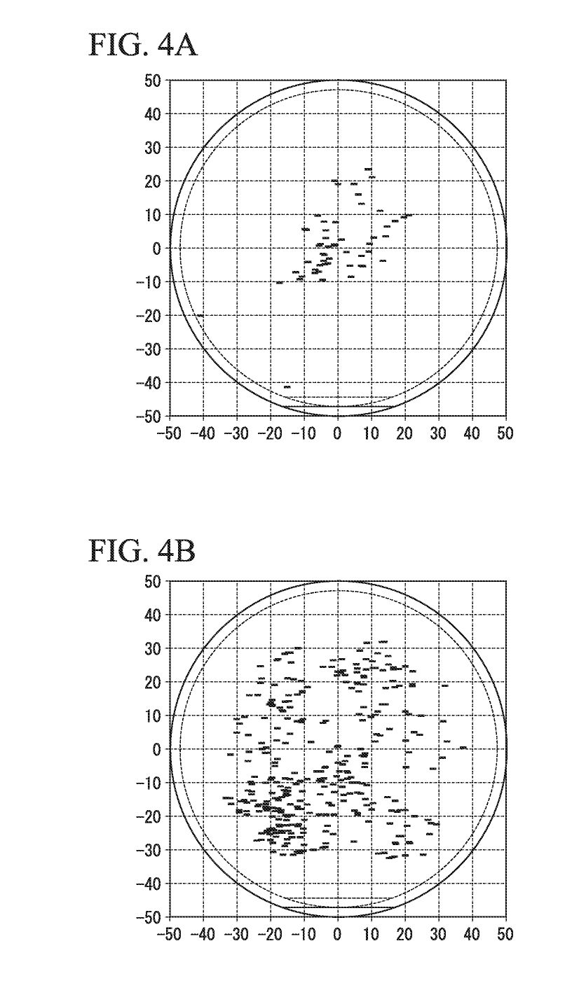

The distribution of the basal plane dislocations appearing on the surface of the laminated epitaxial layer was determined. The distribution of the basal plane dislocations was measured using a photoluminescence (PL) method. The basal plane dislocations emit light having a wavelength of 700 nm or more when irradiated with ultraviolet light. The results thereof are shown in FIG. 4A.

### Comparative Example 1

Comparative Example 1 was conducted in the same way as that of Example 1, except that the supply amount of the raw material gas of the growing SiC single crystal substrate was not changed. In Comparative Example 1, the distribution of the carrier concentration in a thickness direction of the epitaxial layer and the distribution of the basal plane dislocations thereof were determined. Results thereof are shown in FIG. 3B and FIG. 4B.

In FIG. 3A, the results obtained by measuring the distribution of the carrier concentration in a thickness direction of the epitaxial layer in Example 1 are shown. In FIG. 3B, the results obtained by measuring the distribution of the carrier concentration in a thickness direction of the epitaxial layer in Comparative Example 1 are shown. The depth position from the surface of the formed epitaxial layer is indicated in the horizontal axis, and the carrier concentration in the depth position is indicated in the vertical axis.

The carrier concentration in a thickness direction of the epitaxial layer in Example 1 varied widely, as shown in FIG. 3A. The carrier concentration had variations in a depth direction with a width of several ten nm. That is, the epitaxial layer includes high concentration layers and low concentration layers laminated alternately. There were high concentration layers having carrier concentrations three times (at least two times) higher than carrier concentrations of low concentration layers adjacent thereto.

In contrast, the carrier concentration in a thickness direction of the epitaxial layer in Comparative Example 1 had almost no variation, as shown in FIG. 3B. In addition, high concentration layers and low concentration layers were not laminated alternately.

FIG. 4A shows the results obtained by measuring the distribution of the basal plane dislocations of the epitaxial layer in Example 1. FIG. 4B shows the results obtained by measuring the distribution of the basal plane dislocations of the epitaxial layer in Comparative Example 1. The positions in the horizontal axis and the vertical axis correspond to the positions from the center of the SiC single crystal substrate.

The comparison of FIG. 4A with FIG. 4B reveals that the basal plane dislocation density in Example 1 was lower than the basal plane dislocation density in Comparative Example 1. The basal plane dislocation density in Example 1 as shown in FIG. 4A was 0.79 cm⁻² and the basal plane dislocation density in Comparative Example 1 as shown in FIG. 4B was 4.80 cm⁻². The results in which the basal plane dislocations appearing on the surface of the epitaxial layer decreased even though the same SiC single crystal substrate was used revels that the basal plane dislocations were converted to the threading edge dislocations.

### DESCRIPTION OF REFERENCE NUMERALS

1 SiC single crystal substrate
2 Carrier concentration variation layer
2A High concentration layer
2B Low concentration layer
2′ Buffer layer
3 Drift layer
10, 11 SiC epitaxial wafer

1. A SiC epitaxial wafer comprising: a SiC single crystal substrate; and a carrier concentration variation layer disposed on one face side of the SiC single crystal substrate,
wherein the carrier concentration variation layer comprises: high concentration layers in which carrier concentrations thereof are higher than carrier concentrations of adjacent layers; and low concentration layers in which carrier concentrations are lower than in adjacent layers, and the high concentration layers and the low concentration layers are laminated alternately.

2. The SiC epitaxial wafer according to claim 1, wherein a respective thickness of the high concentration layers and the low concentration layers is 0.5 μm or less.

3. The SiC epitaxial wafer according to claim 1, wherein a carrier concentration of at least one high concentration layer of the high concentration layers is at least two times higher than carrier concentrations of the low concentration layers adjacent thereto.

4. The SiC epitaxial wafer according to claim 1, wherein an average value of the carrier concentrations of the high concentration layers is at least two times higher than an average value of the carrier concentrations of the low concentration layers.

5. The SiC epitaxial wafer according to claim 1, wherein an average carrier concentration in the carrier concentration variation layer is 1×10¹⁸ atoms/cm³ or more.

6. The SiC epitaxial wafer according to claim 1, comprising: the SiC single crystal substrate; a buffer layer disposed on one face of the SiC single crystal substrate; and a drift layer laminated on the buffer layer,
wherein one portion or an entire portion of the buffer layer is the carrier concentration variation layer.
